(19) United States
(12) Patent Application Publication
(10) Pub. No.: US 2012/0162899 A1
(43) Pub. Date: Jun. 28, 2012

(54) HARD DISK DRIVE MODULE HAVING INDICATING DEVICE

(75) Inventors: KANG WU, Shenzhen City (CN); BO TIAN, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/076,461

(22) Filed: Mar. 31, 2011

(30) Foreign Application Priority Data
Dec. 24, 2010 (CN) 201010605129.7

(51) Int. Cl. H05K 5/00

(52) U.S. Cl. 361/679.33

(57) ABSTRACT

An exemplary hard disk drive module includes a hard disk drive, a bracket supporting the hard disk drive, an interface connecting to the hard disk drive and detecting status of the hard disk drive, and an indicating device connected with the interface for illustrating status of the hard disk drive. The indicating device includes a first indicator, a second indicator, and two wires electrically connecting the first and second indicators with the interface. The indicating device is fixed on the bracket.

### BACKGROUND

1. Technical Field

The disclosure relates to hard disk drive modules, and particularly to a hard disk drive module using an indicating device for indicating a status of the hard disk drive module.

2. Description of Related Art

A hard disk drive is an important data storage apparatus used in a device such as a server, data center or computer system. Many computer systems are equipped with more than two hard disk drives, and indicators are provided for showing the status of each hard disk drive. Generally, plastic light pipes are used to guide light from the indicators to a position visible to users. However, plastic light pipes increase the cost of the system. Also, because light beams from different plastic light pipes may interfere or affect each other, the design of the plastic light pipes is rather complicated and time-consuming.

Therefore, an improved hard disk drive module is desired to overcome the above-described shortcomings.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the disclosure. Moreover, in the drawings, like reference numerals designate corresponding parts throughout the views.

FIG. 1 is an exploded, isometric view of a hard disk drive module in accordance with an embodiment of the disclosure.

FIG. 2 is an assembled view of the hard disk drive module of FIG. 1.

### DETAILED DESCRIPTION

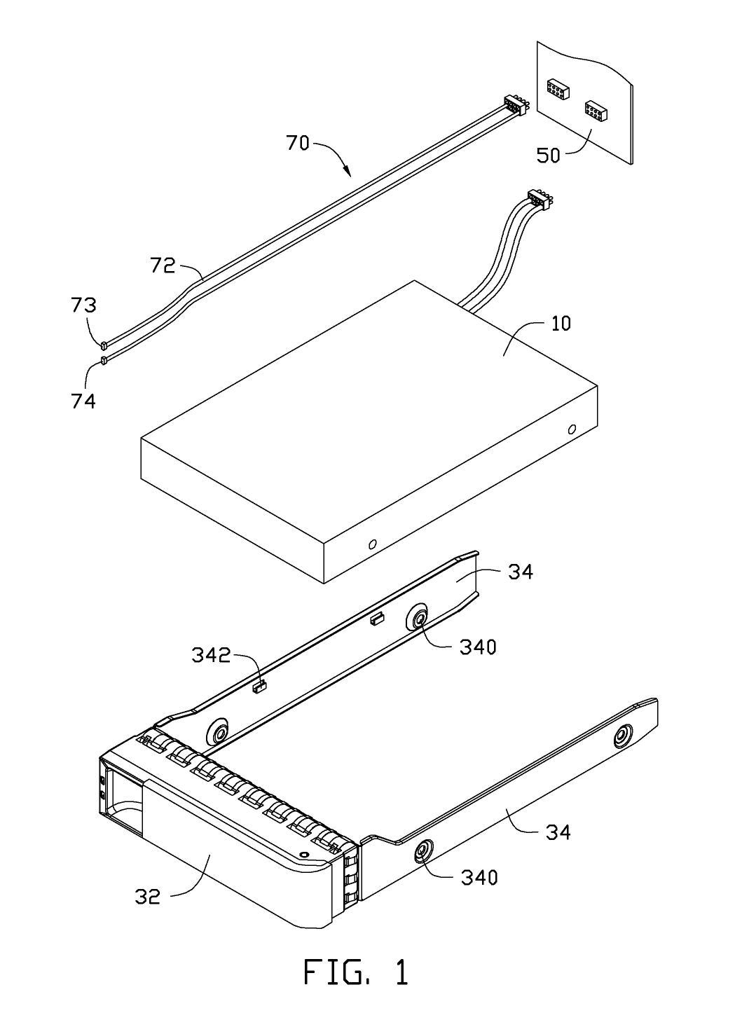

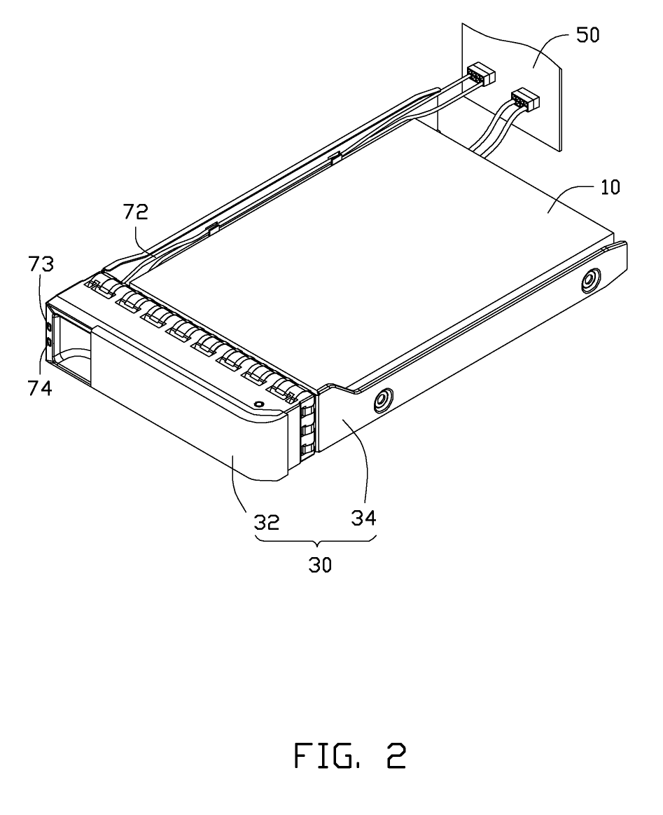

Referring to FIGS. 1 and 2, a hard disk drive module in accordance with an exemplary embodiment is adapted for a device such as a server or a computer. The hard disk drive module comprises a hard disk drive 10, a bracket 30 supporting the hard disk drive 10, an interface 50, and an indicating device 70.

The interface 50 is electrically connected to the hard disk drive 10 for data transmission. The interface 50 can be a parallel ATA interface (PATA), a small computer system interface (SCSI), or a serial ATA interface (SATA). The interface 50 also detects a status of the hard disk drive 10, and then transmits status messages to the indicating device 70. The status can be, for example, active, inactive, or faulty.

The bracket 30 is U-shaped, and comprises a main body 32 and two arms 34 respectively extending outwardly from two opposite ends of the main body 32. The two arms 34 are parallel to each other, and perpendicular to the main body 32. The hard disk drive 10 is sandwiched between the two arms 34. A plurality of screwing holes 340 are respectively defined in the two arms 34, for a plurality of screws (not shown) to extend through and be screwed into the hard disk drive 10. The bracket 30 further comprises a plurality of hooks 342 protruding inwardly from an inner face of one of the arms 34.

The indicating device 70 is electrically connected with the interface 50 for indicating a status of the hard disk drive 10. The indicating device 70 comprises a first indicator 73, a second indicator 74, and two wires 72 electrically connecting the first and second indicators 73, 74 with the interface 50, respectively. The first indicator 73 and the second indicator 74 can be light emitting diode (LED) indicators. The first indicator 73 and the second indicator 74 are located at a front side of the main body 32 of the bracket 30, in order to be visible to users. Two through holes (not labeled) are defined in the main body 32 for respectively exposing the first indicator 73 and the second indicator 74. The wires 72 are fixed on the hooks 342 of the bracket 30. The first indicator 73 is lit up when the hard disk drive 10 is in active state and exchanging data with an outer electronic device like a computer; and the first indicator 73 is turned off when the hard disk drive 10 is in an inactive state and not exchanging data with the outer electronic device. The second indicator 74 is lit up if the hard disk drive 10 is in a faulty state, which means that the hard disk drive 10 needs to be repaired or replaced.

Because the first indicator 73 and the second indicator 74 are located at the front side of the bracket 30 and are visible to users, such persons can readily become aware of the active state, inactive state or faulty state of the hard disk drive 10 by directly observing the first indicator 73 and the second indicator 74. Therefore, the indicating device 70 of the present disclosure is advantageous compared with conventional light guide pipes.

It is believed that the present embodiments and their advantages will be understood from the foregoing description, and it will be apparent that various changes may be made thereto without departing from the spirit and scope of the disclosure or sacrificing all of its material advantages, the examples hereinbefore described merely being preferred or exemplary embodiments of the disclosure.

What is claimed is:

1. A hard disk drive module comprising:
a hard disk drive;
a bracket supporting the hard disk drive;
an interface connecting to the hard disk drive and detecting an operational status of the hard disk drive; and
an indicating device connected with the interface for showing the status of the hard disk drive to a user, the indicating device comprising a first indicator, a second indicator, and two wires electrically connecting the first and second indicators with the interface, the first and second indicators being fixed on the bracket.

2. The hard disk drive module of claim 1, wherein the first indicator is lit up when the hard disk drive is in an active state and exchanging data with an outer electronic device.

3. The hard disk drive module of claim 2, wherein the first indicator is turned off when the hard disk drive is in an inactive state.

4. The hard disk drive module of claim 1, wherein the second indicator is lit up if the hard disk drive is in a fault state.

5. The hard disk drive module of claim 1, wherein the bracket comprises a main body and two arms respectively extending outwardly from two opposite ends of the main body.

6. The hard disk drive module of claim 5, wherein the two arms are parallel to each other, and perpendicular to the main body

7. The hard disk drive module of claim 5, wherein the hard disk drive is sandwiched between the two arms.

8. The hard disk drive module of claim 5, wherein the first indicator and the second indicator are located at a front side of the main body of the bracket, where is visible to users.

9. The hard disk drive module of claim 5, wherein the bracket further comprises hook protruding inwardly from an inner face of one of the arms, and the wires of the indicating device are fixed on the hook.

10. The hard disk drive module of claim 1, wherein the first indicator and the second indicator are light emitting diode indicators.

11. A hard disk drive module comprising:
a bracket comprising a main body and two arms extending outwardly from two opposite ends of the main body, respectively, a space being defined between the arms for receiving a hard disk drive; and
an indicating device comprising a first indicator, a second indicator, and two wires configured for electrically connecting the first and second indicators to the hard disk drive, the first indicator and the second indicator being located at a front side of the main body of the bracket and configured for indicating an operational status of the hard disk drive.

12. The hard disk drive module of claim 11, wherein the first indicator is lit up when the hard disk drive is in an active state and exchanging data with an outer electronic device.

13. The hard disk drive module of claim 12, wherein the first indicator is turned off when the hard disk drive is in an inactive state.

14. The hard disk drive module of claim 11, wherein the second indicator is lit up if the hard disk drive is in a fault state.

15. The hard disk drive module of claim 11, wherein the two arms are parallel to each other, and perpendicular to the main body

16. The hard disk drive module of claim 11, wherein the bracket further comprises a plurality of hooks protruding inwardly from an inner face of one of the arms, and the wires of the indicating device are fixed on the hooks.

17. The hard disk drive module of claim 11, wherein the first indicator and the second indicator are light emitting diode indicators.

18. A hard disk drive module comprising:
a hard disk drive;
a bracket supporting the hard disk drive;
an interface connecting to the hard disk drive, and detecting an operational status of the hard disk drive; and
an indicating device connected with the interface for showing a current status of the hard disk drive, the indicating device comprising a first indicator, a second indicator, and two wires electrically connecting the first and second indicators with the interface, respectively, the first indicator and the second indicator being located at a front side of the bracket.

19. The hard disk drive module of claim 18, wherein the first indicator is lit up when the hard disk drive is in an active state and exchanging data with an outer electronic device, and the first indicator is turned off when the hard disk drive is in an inactive state.

20. The hard disk drive module of claim 11, wherein the second indicator is lit up if the hard disk drive is in a fault state.
